(19) United States
(12) Patent Application Publication
(10) Pub. No.: US 2025/0024759 A1
(43) Pub. Date: Jan. 16, 2025

(54) ELECTROCHEMICAL CHARGE STORAGE DEVICE

(71) Applicant: COMMISSARIAT À L’ENERGIE ATOMIQUE ET AUX ENERGIES ALTERNATIVES, PARIS (FR)

(72) Inventors: Sami OUKASSI, GRENOBLE CEDEX (FR); Tifenn HIRTZLIN, GRENOBLE CEDEX (FR); Massimiliano MELFI, GRENOBLE CEDEX (FR); Elisa VIANELLO, GRENOBLE CEDEX (FR)

(21) Appl. No.: 18/768,818

(22) Filed: Jul. 10, 2024

(30) Foreign Application Priority Data
Jul. 10, 2023 (FR) 2307355

(51) Int. Cl. H10N 70/20; G01N 27/414; H10B 63/00; H10N 70/00

(52) U.S. Cl. CPC H10N 70/253; G01N 27/414; H10B 63/30; H10N 70/021; H10N 70/245; H10N 70/8416

(57) ABSTRACT

An electrochemical storage device includes an ionic transistor and an ionic capacitor, the ionic transistor including a gate electrode, the ionic capacitor including two electrodes, the device further including a connection element able to connect the gate electrode of the ionic transistor to a first of both electrodes of the ionic capacitor.

### CROSS-REFERENCE TO RELATED APPLICATIONS

This application claims priority to French Patent Application No. 2307355, filed Jul. 10, 2023, the entire content of which is incorporated herein by reference in its entirety.

### FIELD

The technical field of the invention is that of storage components, in particular electrochemical charge storage components.

In particular, the invention relates to an electrochemical charge storage device that can be used in neuromorphic applications.

### BACKGROUND

The use of artificial intelligence algorithms for a wide range of applications has exploded in recent years. These algorithms often require so-called neuromorphic architectures, which aim to mimic the synaptic processing that occurs in the human brain. Thus, neuromorphic architectures (or circuits) are electronic circuits designed to emulate the behaviour of biological neurons and neural networks.

Neuromorphic architectures, such as IBM™ Resistive Processing Units (RPUs), are partly based on resistive memory devices that use a network of crossed elements to achieve good performance in terms of memory density, energy efficiency and speed, by reducing data movement during computation and taking advantage of multi-level analogue states. Such resistive memory devices can accelerate formation of deep neural networks using little energy. Indeed, it is possible to mimic the operation of a biological neuron using an array of resistive memories associated with respective synaptic weights.

Existing devices based on conductive filaments or phase-change materials suffer from excessive writing noise. In these devices, it is difficult to reduce noise and lower the switching voltage while ensuring long-term data retention, which represents a significant limitation in terms of accuracy, energy efficiency and scalability of these devices. To implement efficient neuromorphic systems, it is therefore preferable to use resistive memory elements that switch using a different mechanism to that used in filament-forming or phase-change devices.

For this reason, a new class of component has recently been studied for these neuromorphic applications: the ionic transistor, which can be used as a synaptic transistor. The operation of the ionic transistor is based on the displacement of ions between the source and drain, which enables the conductance value of the transistor to be modified. Such a transistor is especially described in the paper by Nguyen et al. An Ultralow Power LiₓTiO₂-Based Synaptic Transistor for Scalable Neuromorphic Computing”, published in Advanced Electronic Materials in 2022.

The ionic transistor can advantageously be in a plurality of states (several dozens), each state corresponding to a respective conductance value. As with filamentary or phase-change resistive memories, these states are non-volatile: when a gate voltage (bias) is stopped to be applied to the ionic transistor, it keeps its conductance value. However, for some neuromorphic applications, it is desirable for the conductance value of the transistor to “relax” over time, i.e. to decrease over time when no gate voltage is applied. Furthermore, this relaxation should be controllable.

The invention improves the situation.

### SUMMARY

An aspect of the invention provides a solution to the problem previously discussed, by providing an electrochemical charge storage device (hereinafter referred to as an “electrochemical storage device”) comprising an ionic transistor and an ionic capacitor, wherein the gate of the ionic transistor is connected, directly or indirectly, to one of the electrodes of the ionic capacitor. Due to the presence of the ionic capacitor, a relaxation of the conductance level of the transistor is indeed observed, when no voltage is applied to the gate. The value of the transistor conductance thus decreases, with a time constant that can be adjusted, especially by applying a voltage to the electrodes of the ionic capacitor and modulating the value of this voltage. The result is thus a device with a multitude of conductance levels, which requires a very small amount of energy to shift from one conductance level to another, and whose conductance relaxes over time. Such a device effectively simulates behaviour of a biological synapse, and is of particular interest in the design of complex and powerful neuromorphic systems.

Furthermore, it is possible to manufacture such a device on a same substrate, by sharing a large part of the manufacturing steps for the ionic transistor and the ionic capacitor. This makes it possible to obtain a compact device whose manufacture is relatively simple and inexpensive.

One aspect of the invention thus relates to an electrochemical charge storage device comprising an ionic transistor and an ionic capacitor, the ionic transistor comprising:
a layer forming an ion reservoir, called reservoir layer;
a source electrode in contact with a part of the reservoir layer;
a drain electrode in contact with another part of the reservoir layer, the drain electrode and the source electrode being physically separated from each other, the source electrode and the drain electrode each being of an electrically conductive material; and
a gate electrode of an electrically conductive material, the gate electrode being separated from the reservoir layer by an ionic conductive layer of an ionic conductive and dielectric material, the ionic conductive layer being in contact with the source electrode and with the drain electrode;
the ionic capacitor comprising two electrodes, each of the two electrodes being of an electrically conductive material, the ionic capacitor comprising an ionic conductive layer separating the two electrodes of the ionic capacitor, the ionic conductive layer of the ionic capacitor being of an ionic conductive and dielectric material;
the device further comprising a connection element able to connect the gate electrode of the ionic transistor to a first of both electrodes of the ionic capacitor.

In other words, the gate electrode of the ionic transistor is able to be connected to one of the two electrodes of the ionic capacitor.

The reservoir layer is a layer of a material comprising ions of some type (for example Li+). The reservoir layer may be in a material referred to as an “ion insertion material”, or “insertion compound” or “ion intercalation material”, i.e. a material which allows the penetration of some type of ions, without altering its properties. In the following, the reservoir layer is also referred to as the “channel layer” or “ion intercalation material layer”. It is noted that, above, “ionic conductive material” designates a material which is conductive for the same ions as those of the reservoir layer.

The connection element may be any electronic component or any element able to connect, at least at a given moment, the gate electrode of the ionic transistor to the first electrode of the ionic capacitor. For example, the connection element may be an element of an electrically conductive material, such as a conductive via or a layer of a conductive material (it is noted that where nothing is set out, “conductive” means “electrically conductive”), which enables the ionic transistor and the ionic capacitor to be connected in a simple manner. The connection element may, in other embodiments, be a component which allows the time instants during which the gate of the ionic transistor is connected to the first electrode of the ionic capacitor to be controlled, such as a switch or a multiplexer.

The “first electrode” here designates the ionic capacitor electrode that can be connected, via the connection element, to the gate electrode. This terminology is used here to simplify reading. It is understood that the gate electrode of the ionic transistor may be connected to any of the electrodes of the ionic capacitor.

It is noted that the terms “gate”, “source”, “drain” may be used in place of the terms “gate electrode”, “source electrode”, “drain electrode”, respectively, for the sake of simplification. Also, the term “terminal” may be used in place of “electrode” for ionic capacitor.

In the absence of an ionic capacitor connected to the gate of the ionic transistor, the same remains in a non-volatile state when no voltage is applied to its gate. This means that when the ionic transistor is in a state corresponding to some value of conductance, this value remains substantially constant when a gate current is no longer applied. By connecting the gate of the ionic transistor to one of the electrodes of the ionic capacitor, the ionic transistor is partially “discharged” into the ionic capacitor, resulting in a decrease in the value of the conductance of the ionic transistor over time, referred to here as “relaxation of the conductance state of the ionic transistor”. This property is of interest especially within the scope of neuromorphic applications, as it more faithfully reproduces behaviour of biological synapses.

Furthermore, making such a device can be beneficially simplified because the ionic transistor and the ionic capacitor use similar layers of materials. Thus, some manufacturing steps can be shared, as detailed hereinafter.

When the ionic capacitor has a “stacked” structure on the substrate (in that the electrodes extend along a direction that corresponds to the main direction of the substrate), the terminology “top electrode/bottom electrode” can be used. The bottom electrode corresponds to the electrode closest to the substrate, while the top electrode corresponds to the electrode furthest from the substrate.

In one or more embodiments, one of the source electrode and the drain electrode of the ionic transistor is connected to a second of the two electrodes of the ionic capacitor, the second electrode being distinct from the first electrode.

Here, “second electrode” designates the other electrode of the ionic capacitor (i.e., the one that is not intended to be connected, via the connection element, to the gate electrode of the ionic transistor). For example, the second electrode may be the top electrode and the first electrode may be the bottom electrode of the ionic capacitor.

In one or more embodiments, the connection element is an element able to connect, directly or indirectly, the gate electrode of the ionic transistor to the first electrode of the ionic capacitor.

By “directly”, it is understood that there is no intermediate component other than the connection element between the ionic transistor and the ionic capacitor. Conversely, “indirectly” indicates the presence of an intermediate component between the ionic transistor and the ionic capacitor, in addition to the connection element.

In one or more embodiments, the connection element may be one of a layer of electrically conductive material, a conductive via, a switch or a multiplexer.

When the connection element is a layer of electrically conductive material or a conductive via, a same voltage can be applied to the gate of the ionic transistor and to the terminals of the ionic capacitor, thereby both placing the ionic transistor in a given conductance state and modifying capacitance value of the ionic capacitor. These two actions are therefore done in a shared manner.

When the connection element is a switch or a multiplexer, it is possible on the one hand to place the ionic transistor in a given conductance state and/or on the other hand to charge the ionic capacitor. These two actions are therefore performed separately (or offset), which offers greater freedom in controlling relaxation of the ionic transistor. In particular, this makes it possible to introduce controlled delay on relaxation (i.e. to control the moment at which it is desired for the conductance value of the ionic transistor to start decreasing) and to control the relaxation speed of the conductance state of the ionic transistor. Schematically, the relaxation speed partly depends on the capacitance of the ionic capacitor: the higher the capacitance, the slower the relaxation. The relaxation speed also partly depends on the conductance of the ionic transistor: the higher the conductance, the faster the relaxation. Furthermore, it is possible to interrupt or suspend relaxation by interrupting or suspending connection between the gate of the ionic transistor and the first electrode of the ionic capacitor.

In one or more embodiments, the device further comprises the ionic conductive layer of the ionic transistor and the ionic conductive layer of the ionic capacitor are common.

By “common”, it is understood that the device comprises a “continuous” ionic conductive layer (i.e. without discontinuities, for which there is no interruption) which acts both as the ionic conductive layer of the ionic transistor and as the ionic conductive layer of the ionic capacitor.

In other words, according to these embodiments, the same ionic conductive layer connects the source and drain of the ionic transistor and separates both electrodes of the ionic capacitor. This makes it possible to share deposition of such a layer when manufacturing a device according to an aspect of the invention.

For example, the ionic conductive and dielectric material may be a lithium phosphorus oxynitride LiPON, a lithium silicon phosphorus oxynitride LiSiPON, a lithium germanium phosphorus sulphide LGPS, a lithium lanthanum zirconium oxide LiLaZrxO_{y} or a lithium lanthanum tantalum oxide LiLaTaOₓ.

LiPON can be used for an ionic transistor and an ionic capacitor operating on the basis of lithium Li+ ions (i.e. whose operation relies on the circulation of Li+ ions). In these embodiments, the channel of the ionic transistor can be made of a Li+ ion insertion material, for example a transition metal oxide capable of intercalating Li+ ions. It will be appreciated that the invention is applicable to other charge-carrying ions, for example Na+, H+, K+, Cu+ ions etc.

The electrically conductive material of which the electrodes of the ionic capacitor and/or the source, drain or gate electrodes of the ionic transistor are made may be, for example, one of: titanium (Ti), tungsten (W), molybdenum (Mo), nickel (Ni) or platinum (Pt).

The reservoir layer may be made, for example, from one of the following materials: titanium dioxide (TiO₂), lithium cobalt dioxide (LiCoO₂), lithium niobate (LiNbOₓ), tungsten trioxide (WO₃), vanadium oxide (VOₓ), nickel oxide (NiOₓ), manganese oxide (MnOₓ)—and generally transition metal oxides, molybdenum disulphide (MoS₂), graphene.

In some embodiments, the gate electrode of the ionic transistor and said first electrode of the ionic capacitor may be common.

By “common”, it is understood that the device comprises a “continuous” layer (i.e. without discontinuities, for which there is no interruption) of electrically conductive material which acts both as the gate electrode of the ionic transistor and as the first electrode of the ionic capacitor. For example, one end of the continuous layer corresponds to the gate electrode of the transistor, and the other end to the bottom electrode of the capacitor.

In these embodiments, it is therefore a same layer of electrically conductive material which acts simultaneously as the gate electrode, the connection element and the first electrode of the ionic capacitor. This simplifies manufacture of the device and also makes it more compact.

In some embodiments that are alternative or complementary to the previous ones, the source electrode of the ionic transistor, the drain electrode of the ionic transistor and the second electrode of the ionic capacitor may be of a same electrically conductive material and have a same thickness.

The electrically conductive material may be, although not exclusively, the same as that of the gate electrode of the ionic transistor and the first electrode of the ionic capacitor.

In particular, if the one of the drain electrode and the source electrode of the ionic transistor connected to the second electrode of the ionic capacitor is called connection electrode of the ionic transistor, then the connection electrode of the ionic transistor and the second electrode of the ionic capacitor may be common.

In other words, the device comprises a “continuous” layer (i.e. without discontinuities) which acts both as the connection electrode of the ionic transistor and as the second electrode of the ionic capacitor. For example, one end of the continuous layer corresponds to the connection electrode of the transistor, and the other end to the second electrode of the capacitor.

In other words, a same layer of electrically conductive material can serve both as the connection electrode (source or drain) of the ionic transistor and as the second electrode of the ionic capacitor.

In embodiments, the ionic transistor and the ionic capacitor may be formed monolithically on a same substrate.

By “formed on a same substrate”, it is understood that the ionic transistor and the ionic capacitor are integrated on a same substrate wafer. This enables the two components to be co-integrated in parallel, with shared manufacturing steps. In particular, at least some layers come from a same deposited and structured layer of material. It should be noted that by substrate, it is meant the raw substrate (i.e. a Si wafer, for example) but also a raw substrate onto which one or more semiconductor or insulating layers have been deposited. By “monolithically”, it is meant “in a single block”. In other words, the ionic transistor and the ionic capacitor are integrated on the same substrate and form an assembly.

For example, the ionic transistor and the ionic capacitor may be mounted to the same level of the substrate.

In particular, the substrate may comprise, on a first level, CMOS-type components, and, on a second level, the ionic transistor and the ionic capacitor. For example, the ionic transistor and the ionic capacitor can be made in “Back End Of Line” on a substrate integrating CMOS, provided that maximum temperatures in the order of 450° C. are complied with.

In embodiments, the substrate may comprise a recess, wherein at least part of the ionic capacitor is housed in the recess.

This increases the exchange area between the lower and top electrodes of the ionic capacitor, and hence the capacitance value of the ionic capacitor.

In these embodiments, the second electrode (bottom electrode) of the ionic capacitor extends along an inner surface of the recess, the ionic conductive layer of the ionic capacitor at least partially overlaps the second electrode of the ionic capacitor, and the first electrode (top electrode) of the ionic capacitor at least partially covers the ionic conductive layer of the ionic capacitor.

In embodiments, the ionic capacitor further comprises an interlayer of an ion reservoir material, the interlayer separating the ionic conductive layer of the ionic capacitor and the electrode, among the two electrodes of the ionic capacitor, other than the first electrode.

Such an implementation makes it possible to further increase value of the capacitance density (in practice, this can be doubled compared with an isoarchitecture without an interlayer).

Another aspect of the invention relates to a neuromorphic processing circuit of the “differential pair integrator” type comprising an electrochemical charge storage device as defined hereinbefore.

A differential pair integrator circuit (also referred to as “diff-pair integrator”) is an analogue artificial synapse described, for example, in the paper by G. Indiveri et al. “Neuromorphic silicon neuron circuits”, Frontiers in Neuroscience, published on 31 May 2011, or in the paper by M. Payvand et al. “Self-organization of an inhomogeneous memristive hardware for sequence learning”, Nat Commun 13, 5793 (2022). It is possible to replace the ionic transistors in these circuits with charge storage devices according to an aspect of the invention, to induce relaxation of the conductance state of the ionic transistors and thus get closer to the behaviour of biological synapses. Furthermore, capacitors connected to the transistors can provide charge storage for other blocks of the circuit.

Another aspect of the invention relates to a method for manufacturing an electrochemical charge storage device as defined previously, the method successively comprising:
depositing, onto a substrate, a first layer of electrically conductive material, and structuring said first layer so as to obtain a first part of first layer and a second part of first layer having no contact points, the first part of first layer corresponding to one electrode among a source electrode and a gate electrode of the ionic transistor, the second part of first layer corresponding to the other electrode among the source electrode and the drain electrode of the ionic transistor and to an electrode of the ionic capacitor;
depositing the reservoir layer, the reservoir layer being in contact with the first part of first layer and with the second part of first layer;
depositing an ionic conductive layer of an ionic conductive and dielectric material, the ionic conductive layer at least partially covering the first part of first layer, the entire reservoir layer and at least partially the second part of first layer; and
depositing a second layer of electrically conductive material at least partially covering the ionic conductive layer, the second layer of electrically conductive material having no physical contact points with the first layer of electrically conductive material, the second layer of electrically conductive material forming a gate electrode of the ionic transistor and another electrode of the ionic capacitor.

It is thus possible to manufacture an electrochemical storage device monolithically on a single substrate, by sharing some steps to manufacture both the elements making up the ionic transistor and the elements making up the ionic capacitor. This is made possible by the fact that the ionic transistor and the ionic capacitor are made up of similar layers of material. This results in simplicity of manufacture, and a compact electrochemical storage device adapted to neuromorphic applications.

In particular, the deposition of at least one of the first layer of electrically conductive material, the ionic conductive layer and the second layer of electrically conductive material may be a conformal deposition.

By “conformal deposition”, it is meant a deposition embracing the surface on which the layer of material is formed and having a same thickness over its entire deposition surface.

Prior to the above steps, the method may comprise: structuring the substrate to form a recess in the substrate, wherein depositing the first layer of electrically conductive material, the ionic conductive layer and the second layer of electrically conductive material successively take place on the thus structured substrate.

Thus, a single layer can be deposited and then structured to form several elements of the electrochemical energy storage device according to an aspect of the invention.

The invention and its different applications will be better understood upon reading the following description and upon examining the accompanying figures.

### BRIEF DESCRIPTION OF THE FIGURES

Further characteristics and benefits of the invention will become apparent upon reading the description, which may be read in conjunction with the figures. These figures are set forth by way of indicating and in no way limiting purposes of the invention.

FIGS. 1a and 1b represent an ionic transistor of the state of the art.

FIGS. 2a and 2b represent an ionic capacitor of the state of the art.

FIG. 3a represents an example of an electronic circuit for relaxing conductance value of an ionic transistor according to one embodiment of the invention.

FIG. 3b represents an equivalent model of the electronic circuit of FIG. 3a.

FIGS. 4a to 4f illustrate steps of a method for manufacturing a storage element according to one embodiment of the invention.

FIG. 5 represents an example of a flow diagram of a method for manufacturing a storage element according to one embodiment of the invention.

FIG. 6 represents an example of a flow diagram of a method for using a storage element according to one embodiment of the invention.

FIG. 7 represents several curves illustrating relaxation of the normalised conductance of the ionic transistor as a function of time, for several values of the ionic capacitor.

FIG. 8 represents an example of a storage element according to another embodiment of the invention.

### DETAILED DESCRIPTION

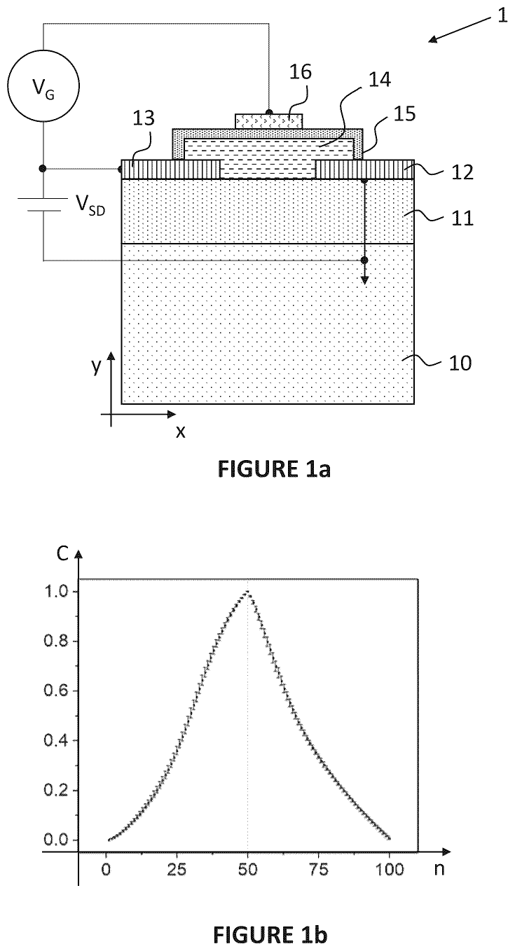

FIG. 1a represents an ionic transistor 1 according to the state of the art.

The ionic transistor 1 is an analogue transistor mounted to a substrate 10, especially of silicon Si, covered with a layer 11 of dielectric material (for example, silicon dioxide SiO₂), which comprises a channel 14 having variable electrical conductivity, a source electrode 13 (also referred to simply as “source”) and a drain electrode 12 (also referred to simply as “drain”). It is noted that in some embodiments the assembly formed by the substrate 10 and dielectric layer 11 may be replaced with a single layer of dielectric material. The drain 12 and source 13 are separated from each other by the channel 14, so that the drain 12 and source 13 have no point of physical contact. For example, drain 12 and source 13 may be deposited onto two portions of a surface of layer 11 of dielectric material, both portions of the surface of layer 11 of dielectric material being spaced apart by, for example, a few tens of nanometres. The drain 12 and the source 13 are of an electrically conductive material. Channel 14 is of an ion-insertion material. It is noted that the source and drain electrodes may be interchanged (in particular, in FIG. 1a, electrode 12 may represent the source and electrode 13 may represent the drain).

The ionic transistor 1 further comprises a layer 15 of a material that is both ionic conductive and dielectric, separating the channel 14 from an electrode 16 called the gate, positioned at the upper surface of the layer 15 of material that is both ionic conductive and dielectric. The gate electrode 16 (also known simply as the “gate”) is of an electrically conductive material. Layer 15 therefore allows ion transport between channel 14 and gate electrode 16, but blocks electron transport. It is understood that layer 15 is conductive for the same ions as the ion-insertion material making up channel 14. For example, if channel 14 is of a material allowing intercalation of Li+ ions, the material of layer 15 is conductive for Li+ ions.

The ionic transistor 1 can be manufactured by successively depositing (and structuring) layers making it up (depositing the layers forming the drain 12 and the source 13, then depositing the layer 14 forming the channel, then depositing the layer 15 of ionic conductive and dielectric material, and finally depositing the layer 16 forming the gate electrode 16), for example by a lithography method (such as photolithography or electron lithography).

The channel 14 is of an ion insertion material, the electrical conductivity of which depends on its oxidation level. For example, the channel may be of an inert material such as lithiated components like LiₓCoO₂, LiₓNiO₂, LiₓMn₂O₄, LiₓV₂O₅, LiₓWO₃, LiₓMO₃, LiₓTi₅O₁₂, where x is the fraction of lithium in the component.

In a non-limiting manner, the channel 14 may comprise LiCoO₂, the layer 15 of ionic conductive and dielectric material may comprise lithium phosphorus oxynitride (LiPON), which is a material that can conduct Li+ ions from the channel 14.

It is noted that other layers may be added to the ionic transistor 1, for example an interlayer of an ion insertion material located between the channel layer 14 and the layer 15 of ionic conductive and dielectric material. Furthermore, it is noted that the structure of the ionic transistor may differ from the example represented in FIG. 1a. For example, according to some embodiments, channel layer 14 may completely cover drain 12 and source 13, as in US application 10,429,343 for example.

The oxidation level of channel 14 can be varied by applying a voltage VG applied between gate 16 and source 13. When a voltage VG is applied between gate 16 and source 13, this induces migration of ions between gate 16 and channel 14, which has the effect of modifying electrical conductance of channel 14 between source 13 and drain 12, and hence the logic state of the transistor, a logic state being associated with a respective electrical conductance value of the transistor. The different (normalised) conductance values of the ionic transistor as a function of the voltage applied between gate 16 and source 13 are represented in FIG. 1b. By conductance of the ionic transistor, it is meant the electrical conductance of channel 14.

To obtain the curve of FIG. 1b, successive voltage square slots have been applied between gate 16 and source 13. In the example of FIG. 1b, each voltage square slot has an amplitude of ±100 mV and a width of 0.1 second. These values are given by way of non-limiting example. The curve of FIG. 1b represents the variation in transistor conductance (ordinate) as a function of the number n of voltage square slots (abscissa). To obtain the curve of FIG. 1b, 50 successive pulses of negative amplitude have been applied (increasing part of the curve, called the potentiation phase), then 50 successive pulses of positive amplitude have been applied (decreasing part of the curve, called the depression phase).

It appears from FIG. 1b that the conductance of channel 14 can be reversibly modified according to the voltage VG applied between gate 16 and source 13. Furthermore, the variation in the value of conductance is linear during the application of a non-zero constant value of voltage. It increases linearly when a voltage square slot of negative amplitude is applied, and decreases linearly when a voltage square slot of positive amplitude is applied. Furthermore, the application of a voltage square slot of positive amplitude “cancels out” effects of the application of a voltage square slot of the same duration and opposite amplitude (and vice versa), in that it returns the conductance value to the initial value.

It is thus possible to modify conductance of the ionic transistor 1 of FIG. 1a by varying the value of the voltage VG applied between the gate 16 and the source 13. Once the ionic transistor has a certain conductance value, a voltage V_{SD} is applied between source 13 and drain 12 and a current circulates, the value of the current intensity being set by the conductance value of the transistor.

The different conductance values associated with the different current pulse numbers correspond to logic states (or “conductance states”). Each logic state is non-volatile, and the transition from one logic state to the next requires very little energy (for example, a quantity of energy per active area in the order of fJ/μm²). Further, as appears from FIG. 1b, a large number (several tens) of logic states can be achieved in potentiation and depression in a controlled manner (via the applied voltage VG), with, as mentioned above, a response linearity that is a function of the conductance range considered.

It is noted that the transition speed between two successive logic states of the ionic transistor partly depends on the thickness of the channel layer 14 (the thickness corresponding to the dimension along the axis y in FIG. 1a): the thinner the channel layer 14, the higher the transition speed between two successive logic states. The thickness of the channel layer 14 can thus be set, for example, between 1 and 500 nm.

The transition speed between two successive logic states also partly depends on the thickness of the layer 15 of ionic and dielectric conductive material: the thinner the layer 15 of ionic and dielectric conductive material, the higher the transition speed between two successive logic states. The thickness of the layer 15 of ionic conductive and dielectric material can thus be set, for example, between 1 and 200 nm.

As detailed above, the ionic transistor is an analogue transistor allowing several tens of states (which is difficult to obtain today from dielectric transistors and with resistive memories), which makes it a component of choice for reproducing the operation of synapses, which, in the human brain, enable neurons to be connected together. In the human brain, neurons are activated when the synapses have accumulated a number of electrical impulses, which is made possible by a transistor with several dozen states.

Furthermore, the ionic transistor makes use of the same electrochemical reaction as a synapse, which gives it excellent energy efficiency, of the same order of magnitude as a human brain synapse.

These properties make the ionic transistor particularly adaptable for neuromorphic applications. However, one limitation remains for these transistors: the time constant, which generally defines the relaxation of a transistor's logic state over time and without bias (i.e. when no gate voltage is applied). As each logic state is non-volatile, the time constant is not adaptable or controllable, which reduces the range of applications for these devices.

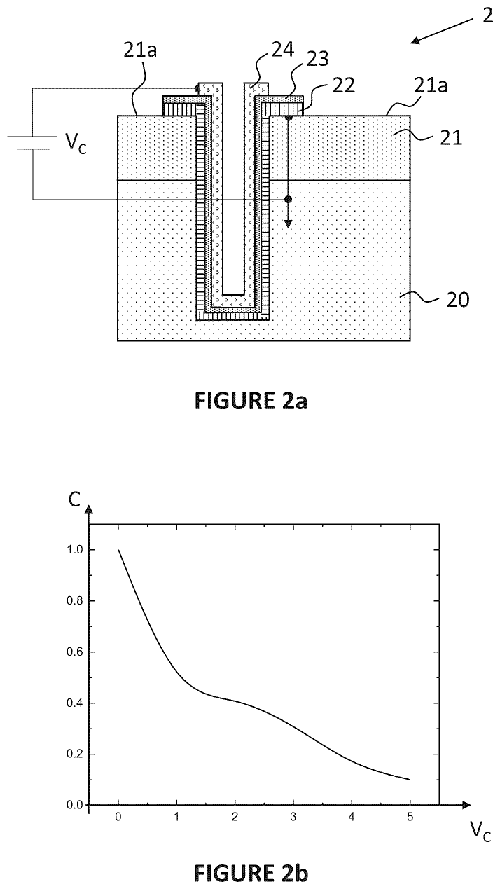

FIG. 2a represents an ionic capacitor 2 (also known as a supercapacitor) according to the state of the art.

An ionic capacitor is an electrochemical energy storage component, of the supercapacitor type, comprised of materials exclusively in solid form. An ionic capacitor can be charged and discharged by connecting it to an electrical circuit. Energy is stored by virtue of changes in the materials making up the ionic capacitor during charging and discharging. When a voltage is applied across the ionic capacitor, depletions/concentrations of ions occur at the two ionic conductor/electrode interfaces.

As represented in FIG. 2a, an ionic capacitor 2 typically comprises a substrate 20 covered with a first dielectric layer 21. The substrate 20 is a raw (i.e. unprocessed) substrate, or it may have already undergone processing such that other electronic components or layers are already present thereon. In the example of FIG. 2a, the substrate 20 and dielectric layer 21 of FIG. 2a have a cavity covered by a layer 22 of electrically conductive material passing therethrough. The cavity is here a blind hole, the bottom of which is located at the substrate 20, in proximity to the lower surface of the substrate 20. This layer 22 of electrically conductive material at least partially covers the “free” surface 21a of the first dielectric layer 21 (i.e. the surface 21a which is not against the substrate 20 and which is not along the cavity formed) on either side of the cavity. The layer 22 of electrically conductive material forms one of the electrodes of the ionic capacitor 2, referred to here as the “bottom electrode”. The layer 22 of electrically conductive material is (at least partially) covered with a layer 23 of a material that is both an ionic conductor and a dielectric (ionic dielectric). This layer 23 of ionic conductor is (at least partially) covered with a layer 24 of electrically conductive material, which forms the other electrode of the ionic capacitor 2, called the “top electrode”. The bottom electrode 22 and the top electrode 24 are thus electrically insulated from each other by the layer 23, which nevertheless allows ions to circulate between both electrodes 22 and 24.

It is noted that the example represented in FIG. 2a is not limiting and that other configurations are possible. For example, in some configurations, the cavity only passes through the first dielectric layer 21. Further, the shape of the cavity is not limiting, and may be replaced with a pore in a porous dielectric layer 21, as described in EP3570307.

In the example of FIG. 2a, the bottom electrode 22, the ionic dielectric layer 23 and the top electrode 24 of the ionic capacitor 2 are disposed according to a MIM (metal-insulator-metal) structure wherein the insulator is an ion-conducting dielectric (ionic dielectric), but other configurations are possible, for example a MOIM (metal-oxide-ionic dielectric-metal) configuration wherein an oxide layer is interposed between the bottom electrode and the ionic dielectric layer, as in application EP3570307.

The presence of the cavity in the assembly formed by the substrate 20 and the dielectric layer 21 of FIG. 2a is not mandatory, but it beenficially makes it possible to increase the effective surface area for accumulating charges between both electrodes 22 and 24. Furthermore, it is noted that the ionic capacitor 2 can be formed in a planar or three-dimensional configuration, a three-dimensional configuration beneficially making it possible to increase the effective surface area for accumulating charges between both electrodes per unit of geometric surface area on the substrate, and therefore to increase the capacitance density of the ionic capacitor 2 (by varying the geometry of the ionic capacitor alone).

The application of a voltage Vc between the bottom electrode 22 and the top electrode 24 induces two distinct physical phenomena: on the one hand, establishment of an electrochemical double layer between the ionic conductor 23 and both electrodes 22 and 24 (appearance of an ionic capacitor), and on the other hand, dielectric bias of the ionic conductor 23 (appearance of a dielectric capacitance). The combination of these two phenomena gives the ionic capacitor a very high power density per unit area, in the order of a few tens of μF/mm², i.e. several orders of magnitude higher than the power densities of MOS or MIM type dielectric components.

Furthermore, as represented in FIG. 2b, the value of the ionic capacitor of capacitor 2 is variable and depends on the voltage Vc applied thereacross (i.e. between both electrodes 22 and 24). As the voltage applied across the ionic capacitor 2 increases, the value of the capacitance decreases over time, from a so-called “nominal” value down to a capacitance value in the order of 10% of the nominal value. Furthermore, the ionic capacitor 2 self-discharges when no voltage is applied thereacross. In this respect, the state of charge of ionic capacitor 2 can be considered volatile.

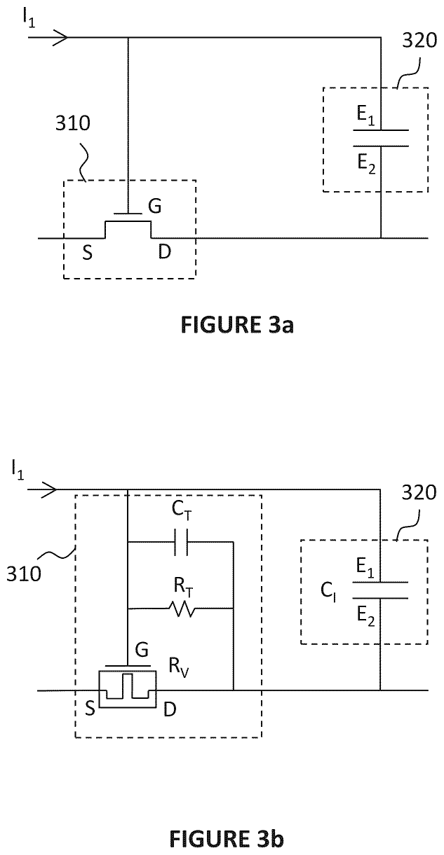

FIG. 3a represents an example of an electronic circuit allowing relaxation of the conductance value of an ionic transistor according to one embodiment of the invention.

The circuit arrangement of FIG. 3a comprises an ionic transistor 310 and an ionic capacitor 320, wherein the gate G of the ionic transistor 310 is connected to an electrode Et of the ionic capacitor 320. Furthermore, in the example of FIG. 3a, the drain D of the ionic transistor 310 is connected to the other electrode E₂ of the ionic capacitor 320. It is noted that the drain and source are interchangeable. Thus, it is possible to connect the source S of the ionic transistor 310 to the other electrode E₂ of the ionic capacitor 320 (the gate G of the ionic transistor 310 always being connected to the electrode E₁ of the ionic capacitor 320). In the case of an ionic capacitor having a “U-shaped” structure as in FIG. 2a, the electrodes E₁ and E₂ may interchangeably correspond to the top electrode and the bottom electrode of the ionic capacitor.

In the example of FIG. 3a, a same voltage is applied to the gate G of the ionic transistor 310 and across the ionic capacitor 320. It is thus possible to place the ionic transistor 310 in a given conductance state, and at the same time to modify value of the capacitance of the ionic capacitor 320. It is noted that this is not mandatory.

For example, the ionic transistor 310 and the ionic capacitor 320 may be separated by an intermediate device, such as a multiplexer or a switch, which allows the gate G of the ionic transistor 310 to be connected to the electrode E₁ of the ionic capacitor 320 only at a given time. Such an intermediate device makes it possible to control when the gate G of the ionic transistor 310 is connected to one of the electrodes of the ionic capacitor 320 (and thus to allow that at other times the gate G of the ionic transistor 310 is not connected to an electrode of the ionic capacitor 320). Thus, it is possible to place the ionic transistor 310 to some conductance value and/or the ionic capacitor 320 to some capacitance value before connecting the gate G of the ionic transistor 310 to one of the electrodes of the ionic capacitor 320. This keeps the ability to maintain the ionic transistor in some non-volatile state, and to control the instant at which it is desired for this state to begin to relax. In other words, this introduces an additional delay for the relaxation of the conductance value of the ionic transistor 310.

Furthermore, the time constant representative of the relaxation speed of the conductance value of the transistor partly depends on the conductance of the ionic transistor 310 and the value of the ionic capacitor. Also, by modifying the conductance value of the ionic transistor 310 and/or the value of the ionic capacitor 320 (before connecting the gate of the ionic transistor 310 to one of the electrodes of the ionic capacitor 320), it is possible to modulate this time constant, and therefore the relaxation speed of the conductance of the ionic transistor 310.

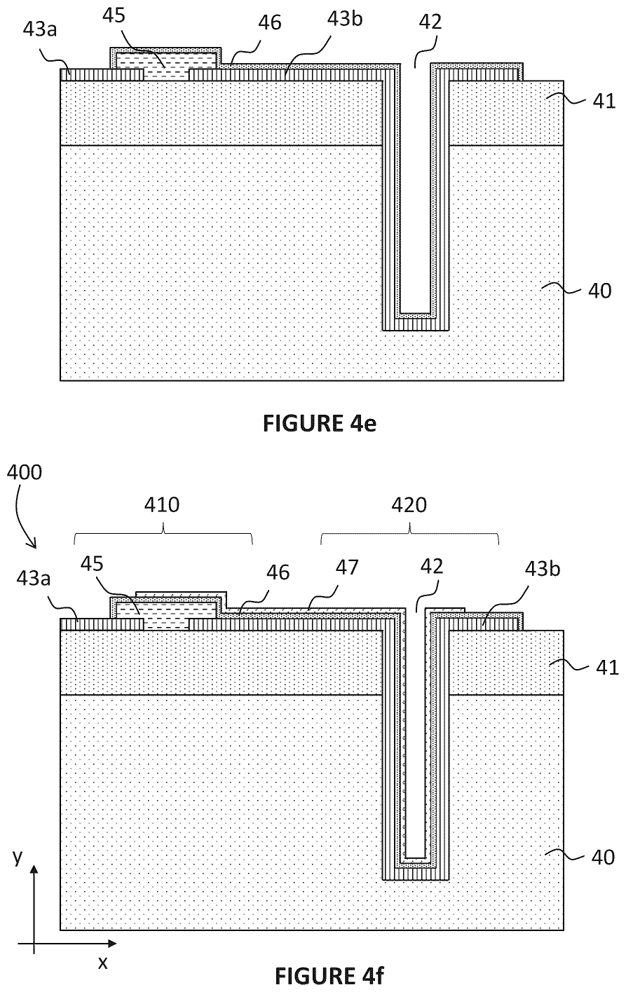

In one or more embodiments, operation of the electrochemical charge storage element 36 may therefore comprise the following steps, represented in FIG. 6:
writing step:
   a first electrical signal (voltage or current) is applied (step 610) between the source and the gate of the ionic transistor 310 to cause the latter to enter a given conductance state; and a second electrical signal (voltage or current) is applied (step 620) between both electrodes of the ionic capacitor 320;
   reading step: the source or drain of the ionic transistor 310 is connected to one of the electrodes of the ionic capacitor 320, while the gate of the ionic transistor 310 is connected to the other electrode of the ionic capacitor 320 (step 630).

As mentioned above, the first electrical signal and the second electrical signal may be the same, as in the diagram in FIG. 3a (current 11). Alternatively, the first electrical signal and the second electrical signal may be two different electrical signals applied independently to the ionic transistor 310 on the one hand (first electrical signal), and to the ionic capacitor 320 on the other hand (second electrical signal). When both electrical signals are different, they may be applied simultaneously or not (in the latter case, they may be applied at two distinct time instants or during two distinct time intervals, which may or may not overlap with each other).

FIG. 3b represents a simplified model of an electrical circuit equivalent to the electronic circuit of FIG. 3a. In this model, the ionic transistor comprises a variable resistor R_{V}, as well as a resistor R_{T} and a capacitor C_{T}, the resistor R_{T} and the capacitor C_{T} both being connected to the gate G via one of their terminals, and to the drain D via the other of their terminals. Resistor R_{T} corresponds to the ionic resistance of the transistor, due to the migration of ions from the gate to the channel. The capacitor C_{T} corresponds to the geometrical capacitance of the ionic transistor, i.e. the “dielectric” capacitance of the ionic transistor 310.

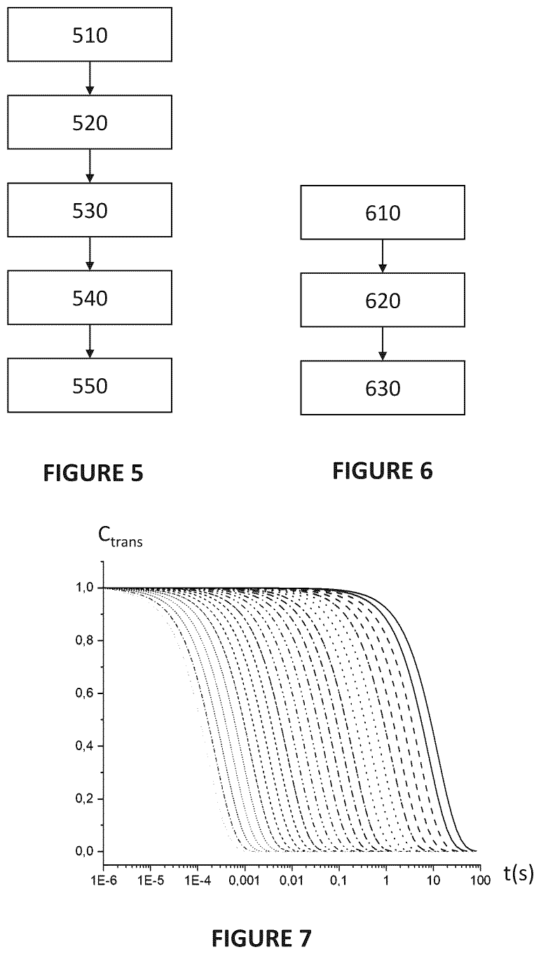

By virtue of the connection of the gate of the ionic transistor 310 to an electrode of the ionic capacitor 320, a partial “discharge” of the ionic transistor 310 towards the ionic capacitor 320 occurs. This results in relaxation of the conductance value of the ionic transistor 310, as represented in FIG. 7.

The curves in FIG. 7 have been obtained by simulation, using the approximate equivalent model of FIG. 3b, once the ionic transistor is in a given conductance state (and no gate voltage is applied). More precisely, several sets of curves are represented in FIG. 3b (each set of curves being represented by a same type of line, for example a solid line, a broken line, a series of dots more or less close together, an alternation of one or more dashes and one or more dots, etc.). Each set of curves corresponds to a same nominal value of total capacitance, the total capacitance being the sum of the capacitances of the capacitor C_{T} of the ionic transistor and the ionic capacitor C_{I}. To obtain the different curves of a same set of curves, the value of the ionic capacitor C_{I} has been modulated by applying one or more voltage values across the ionic capacitor (as explained above with reference to FIG. 2b, the value of the capacitance of the ionic capacitor varies as a function of the voltage applied across the ionic capacitor).

The curves in FIG. 7 illustrate the relaxation of the conductance of the ionic transistor over time: the value of the conductance decreases with time. Thus, it appears that connecting an electrode of an ionic capacitor to the gate of the ionic transistor induces volatility in the conductance state of the ionic transistor.

Furthermore, the curves in FIG. 7 illustrate that the relaxation speed depends on the value of the total capacitance. It is thus possible to modify the value of the total capacitance (especially by modulating the value of the ionic capacitor by applying a voltage across the ionic capacitor) to vary the relaxation speed of the conductance of the ionic transistor.

As mentioned previously, the ionic transistor and the ionic capacitor are two components which use common layers in their operation (especially the ion-conducting active layers 15 and 23 and the layers forming the electrodes 12, 13, 16, 22, 24). This makes it possible to make a storage element with the characteristics of the circuit in FIG. 3a by co-integration of an ionic transistor and an ionic capacitor on a same substrate, wherein some manufacturing steps of the two components are shared.

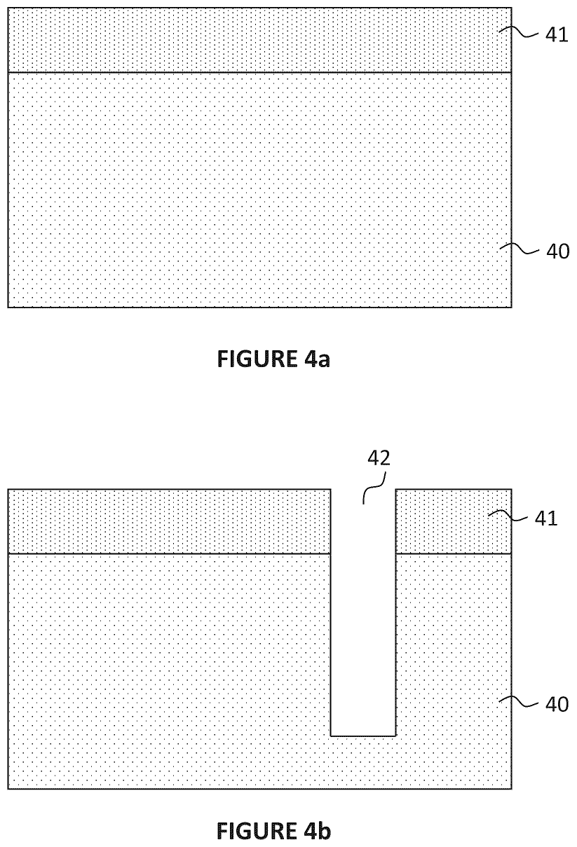

It is thus possible to produce a storage element having the same characteristics as the circuit represented in FIG. 3a by depositing successive layers, as now described with reference to FIGS. 4a to 4f.

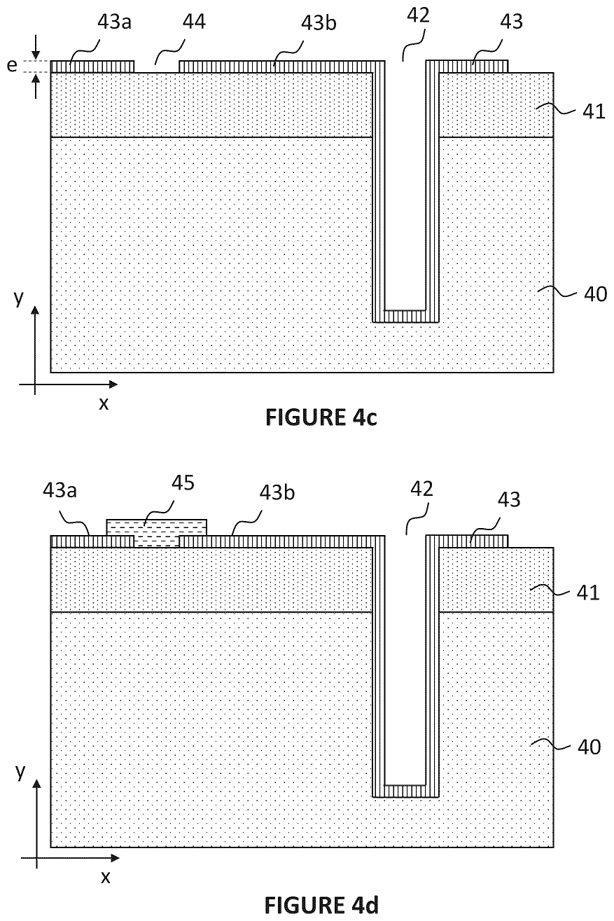

FIGS. 4a to 4f illustrate steps of a method for manufacturing a storage element according to one embodiment of the invention. The flow chart for this manufacturing method is represented in FIG. 5.

In a first step 510 (FIG. 5) of the method, an electrically insulating layer can be deposited onto a substrate. This step is illustrated in FIG. 4a.

As represented in FIG. 4a, an electrically insulating layer 41 (for example of a dielectric material) is formed on a substrate 40, for example by a full wafer deposition method. The substrate 40 may be a wafer of semiconductor material. In some embodiments, this wafer integrates one or more components such as conventional transistors or microsystems. In particular, the storage device of an aspect of the present invention can be integrated in the “Back End Of Line”, i.e. after the CMOS level and higher levels have been made, in the same way as the contacts. It is noted that the ionic conductive layer 41 may constitute the substrate on its own (in some embodiments, therefore, there may be only one dielectric layer 41 which replaces the two layers 40 and 41 of FIGS. 4a to 4f).

The dielectric layer 41 may be comprised of one or more materials for electrical insulation, for example an oxide, nitride, oxynitride, or any material or combination of materials that can act as a chemical and electrical passivation between the substrate 40 and the memory element.

In a non-limiting embodiment, the substrate 40 may be a silicon wafer and the layer 41 may be a silicon oxide layer.

Further, in the first step 510 of the method represented in FIG. 5, the assembly comprised of the substrate and ionic conductive layer may be structured to form a recess for receiving the ionic capacitor. This structuring is represented in FIG. 4b.

As represented in FIG. 4b, the “substrate 40/dielectric layer 41” assembly can be structured to create an opening 42 (or “cavity” or “groove”) perpendicularly to the surface plane of the dielectric layer 41 and the substrate 40. This structuring is carried out through the dielectric layer 41 and the substrate 40, and stops in the substrate volume without passing through it. In the example of FIG. 4b, the opening 42 is a blind hole in the dielectric layer 41 which passes through part of the substrate 40, and the bottom of which is located in proximity to the lower surface of the substrate 40. It is noted that, according to the embodiments, the opening 42 may pass through the substrate to a variable depth, or even only through all or part of the dielectric layer 41 (and therefore not pass through the substrate 40). In some embodiments, structuring may be performed by a photolithography technique (typically comprising deposition of a layer of resin by spin coating on the “substrate 40/dielectric layer 41” assembly, exposure through a mask and development of the resin exposed) followed by plasma etching.

As mentioned with reference to FIG. 2a, the presence of the opening 42 is not mandatory, but it beneficially makes it possible to increase the effective charge surface area for accumulation between both electrodes 43b and 47b.

Referring again to FIG. 5, in a step 520, a first layer of an electrically conductive material can be deposited onto the surface of the substrate, and structured in two parts having no points of contact, one acting as the source electrode of the ionic transistor, and the other comprising both the drain electrode and the bottom electrode of the ionic capacitor.

This step 520 is represented in FIG. 4c: a layer 43 of electrically conductive material is formed on part of the surface of the dielectric layer 41 and at the opening 42 if necessary. The layer 43 of electrically conductive material comprises two parts 43a, 43b separated by a gap 44, such that both portions 43a, 43b of the layer of electrically conductive material 43 have no point of contact with each other and are not electrically connected. In the example of FIG. 4c, part 43b of the layer 43 of electrically conductive material covers part of the unstructured surface of the “substrate 40/dielectric layer 41” assembly (i.e. the part of the surface of the “substrate 40/dielectric layer 41” assembly that is not level with the opening 42) as well as the walls and bottom of the opening 42. As described hereinafter, part 43a acts as the “source” of the ionic transistor of the storage component, and the part 43b acts both as the “drain” of the ionic transistor of the storage component and as the bottom electrode of the ionic capacitor of the storage component. It is noted that the source and drain electrodes may be interchanged (in particular, electrode 43a may represent the drain and electrode 43a may represent the source).

The layer 43 of electrically conductive material may typically be produced by deposition onto the entire surface of the structured “substrate 40/dielectric layer 41” assembly of FIG. 4b (including the walls and bottom of the opening 42), then by structuring in order to make the gap 44 and to give the desired shape and dimensions to the different parts of the layer 43. For example, layer 43 may be deposited by vacuum sputtering, and structuring may be achieved by photolithography followed by dry etching.

In some embodiments, the deposition of the layer 43 of electrically conductive material can beneficially be a conformal deposition on the surface of the structured “substrate 40/dielectric layer 41” assembly, i.e. its thickness is constant over the entire surface. This simplifies the method for manufacturing the electrochemical energy storage element, since a single layer can be deposited along the surface without the need to vary the thickness by adding additional layers.

In some embodiments, the layer 43 may be a titanium metal layer having a thickness e (which corresponds to the dimension along the axis y in FIG. 4c, i.e. along the direction orthogonal to the surface of substrate 40) of between 10 and 200 nm, for example equal to 100 nm.

Referring again to FIG. 5, in a step 530, a layer of an ion insertion material called a channel layer is deposited at the gap between the source electrode and the drain electrode of the ionic transistor, so as to be in contact with both the source electrode and the drain electrode of the ionic transistor.

This step 530 is illustrated in FIG. 4d: a layer 45 of an ion insertion material is formed and structured so as to cover the part of the layer 41 located at the gap 34, as well as portions of the parts 43a and 43b of the layer 43, said portions including the ends of the parts 43a and 43b located at the gap 44. As described hereinafter, this layer 45 constitutes the channel of the ionic transistor of the storage component, and is therefore in contact with the source 43a, the drain 43b and the part of the layer 41 located at the gap 44.

The channel 45 is comprised of an ion insertion material making it possible to intercalate and de-intercalate ions under the application of an electric field and, thus, to change the electrical conductivity of the channel 45 as a function of the intercalation rate. For example, the material making up channel 45 may be a transition metal oxide, and more particularly a metal based on titanium dioxide (TiO₂) nanoparticles having a size of about 10 nm, capable of intercalating lithium (Li+) ions. Channel 45 may, for example, have a thickness in the order of a few nanometres to a few tens of nanometres.

Referring again to FIG. 5, in a step 540, a layer of a material that is both ionic conductive and dielectric may be deposited onto the surface of the element obtained at the end of step 530.

This step 540 is illustrated in FIG. 4e: a layer 46 of ionic conductor and dielectric is deposited onto the surface and structured. The layer 46 is conductive for the same ions as the ion insertion material making up the channel 45. For example, if the channel 45 is of a material allowing intercalation of Li+ ions, the material of the layer 46 is conductive for Li+ ions.

The ionic conductor and dielectric layer 46 is in contact with source 43a and drain 43b, allowing ions to circulate between these two electrodes 43a, 43b via channel 45. The ionic conductor layer 46 covers a portion of the part 43b of the layer 43 of electrically conductive material, said portion of the part 43b of the layer 43 of electrically conductive material including the portion of the part 43b of the layer 43 of electrically conductive material at the opening 42. The layer 46 is “continuous” (in the sense that it has no “holes” or interruptions) from a point of contact with the source 43a and the part of the layer 43b on the other side of the opening 42 to the channel 45. The ionic conductive layer 46 therefore forms both the ionic conductive layer of the ionic transistor and the ionic conductive layer of the ionic capacitor. The layer 46 therefore allows ions to circulate both between the electrodes of the ionic transistor and between the electrodes of the ionic capacitor.

Layer 46 is comprised of an ionic conductive and dielectric material, which allows ions to circulate both between source 43a and drain 43b of the ionic transistor of the storage element, and between both electrodes 43b and 47b of the ionic capacitor of the storage element, while providing electrical insulation between the different electrode pairs. For example, this material may be a lithium phosphorus oxynitride (LiPON). Layer 46 may be a few tens to a few hundreds of nm thick, for example 100 nm. In some embodiments, this layer 46 is deposited by magnetron sputtering. Structuring may be performed by photolithography, for example.

In some embodiments, the deposition of the layer 46 of ionic conductive and dielectric material may beneficially be a conformal deposition onto the surface of the element of FIG. 4d.

Finally, during a step 550 of FIG. 5, a layer of an electrically conductive material may be deposited onto the surface of the element obtained at the end of step 540, and then structured.

This step 550 is illustrated in FIG. 4f, wherein a layer 47 of an electrically conductive material is deposited onto at least a part of the layer 46. After possible structuring, this layer is beneficially “continuous” from a zone of the ionic conductive layer 46 located at the channel 45 to a zone of the ionic conductive layer 46 located on the other side of the opening 42 from the channel 45. This layer 46 forms both the gate of the ionic transistor and the top electrode of the ionic capacitor. In some embodiments, the deposition of the layer 47 of electrically conductive material may beneficially be a conformal deposition onto the surface of the element of FIG. 4e.

For example, layer 47 may be a titanium metal layer having a thickness of 100 nm, deposited by vacuum sputtering. The structuring of layer 47 may be achieved, for example, by photolithography and dry etching.

The above exemplary embodiments focus on a memory device operating on Li+ lithium ions, but it is entirely possible to use other charge-carrying ions, such as Na+, H+, K+, Cu+, etc., in the memory device.

The electrochemical energy storage element 400 of FIG. 4f is represented in a cross-section view on the (x, y) plane. In one or more embodiments, the channel width may be less than 200 nm, such as less than 20 nm. The channel width corresponds to the dimension along the axis z (z being the third axis of an orthonormal reference frame (x, y, z)) of the channel 45 of the ionic transistor 420. The width of the ionic capacitor 420 (i.e. the dimension of the ionic capacitor 420 along the axis z) may be less than 2 μm, such as less than 1 μm. The depth of ionic capacitor 420 (i.e. its dimension along the axis y) may be greater than 2 μm, such as greater than 5 μm.

The electrochemical storage element 400 obtained at the end of the different steps represented in FIGS. 4a to 4f comprises an ionic transistor 410 (with a similar structure to the ionic transistor 1 represented in FIG. 1a) and an ionic capacitor 410 (with a similar structure to the ionic capacitor 2 represented in FIG. 2a), wherein:
the gate electrode of the ionic transistor 410 and the top electrode of the ionic capacitor 420 are connected (and here, formed in a same layer 47 of electrically conductive material), and
the drain electrode of the ionic transistor 410 and the bottom electrode of the ionic capacitor 420 are connected (and herein, formed in a same layer 43b of electrically conductive material).

As previously mentioned, drain 43b and source 43b of ionic transistor 410 are interchangeable. Thus, in the diagram of FIG. 4f, electrode 43a could correspond to the drain, and electrode 43b could correspond to the source of the transistor.

The ionic transistor 410 and the ionic capacitor 420 are monolithically formed on the same level of the substrate 40. As is apparent from above, such an element can be manufactured by sharing some of the manufacturing steps of the transistor and the ionic capacitor (depositing a same layer for both components and structuring).

It will be appreciated that the element 400 of FIG. 4f is only an example of an electrochemical storage element as presented with reference to FIG. 3a. The invention is not limited to this example. For example, the ionic transistor and the ionic capacitor may be two components fabricated separately on two distinct substrates and connected according to the diagram of FIG. 3a, with or without the presence of an intermediate connection element (e.g. a multiplexer or a switch). According to some embodiments, other components may be interposed between the ionic transistor and the ionic capacitor. The ionic transistor and/or the ionic capacitor may also comprise additional layers. For example, an interlayer in an ion insertion material dissociated from that of the ionic transistor can be implemented in the architecture of the ionic capacitor, so as to have a hybrid capacitor. For example, this interlayer can be inserted at the ionic capacitor, between layer 43b and layer 46 in FIG. 4f, i.e. between the bottom electrode and the ionic conductive layer of the ionic capacitor. Such an implementation makes it possible to further increase the value of the capacitance density (in practice, this can be doubled compared with an isoarchitecture without an interlayer), as described for example in the paper by V. Sallaz et al. “Hybrid All-Solid-State Thin-Film Micro-supercapacitor Based on a Pseudocapacitive Amorphous TiO₂ Electrode”, ACS Appl. Energy Mater. 2023, 6, 1, 201-210. Such an interlayer can be obtained from the manufacturing method of FIG. 5: in step 530, the layer of ion insertion material can be deposited onto the entire surface, and structured into two disjoint parts: one corresponding to the channel layer of the ionic transistor, the other corresponding to the interlayer of the ionic capacitor.

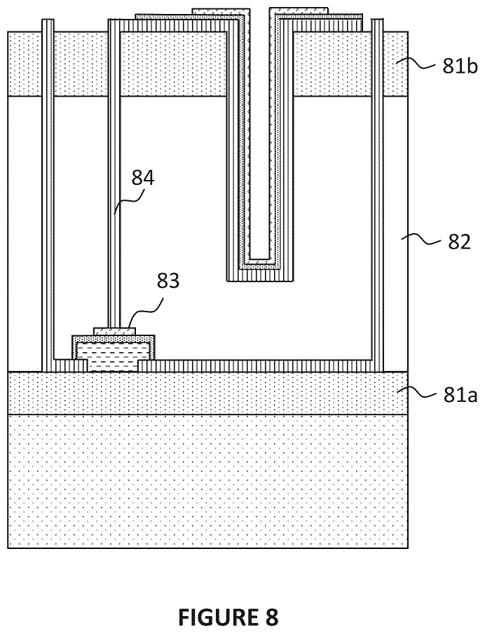

Furthermore, even if the ionic transistor 410 and the ionic capacitor 420 of the element 400 of FIG. 4f are on the same substrate level, it is possible to superimpose the ionic transistor and the ionic capacitor on two different levels vertically with respect to the plane of the substrate to increase integration density of the electrochemical storage element. FIG. 8 represents such an example of a device. In the example of FIG. 8, the ionic transistor is formed on a lower substrate layer 81a and the ionic capacitor is formed on an upper substrate layer 81b, layers 81a and 81b being separated by a layer 82 of dielectric material. The gate 83 of the ionic transistor is connected to the bottom electrode 84 of the ionic capacitor.

The articles “a” and “an” may be employed in connection with various elements and components of compositions, processes or structures described herein. This is merely for convenience and to give a general sense of the compositions, processes or structures. Such a description includes “one or at least one” of the elements or components. Moreover, as used herein, the singular articles also include a description of a plurality of elements or components, unless it is apparent from a specific context that the plural is excluded.

It will be appreciated that the various embodiments and aspects of the inventions described previously are combinable according to any technically permissible combinations. For example, various aspects of the present disclosure may be used alone, in combination, or in a variety of arrangements not specifically described in the embodiments described in the foregoing and is therefore not limited in its application to the details and arrangement of components set forth in the foregoing description or illustrated in the drawings. For example, aspects described in one embodiment may be combined in any manner with aspects described in other embodiments.

The present invention has been described and illustrated in the present detailed description and in the figures of the appended drawings, in possible embodiments. The present invention is not however limited to the embodiments described. Other alternatives and embodiments may be deduced and implemented by those skilled in the art on reading the present description and the appended drawings.

In the claims, the term “includes” or “comprises” does not exclude other elements or other steps. The different characteristics described and/or claimed may be beneficially combined. Their presence in the description or in the different dependent claims do not exclude this possibility. The reference signs cannot be understood as limiting the scope of the invention.

The invention claimed is:

1. An electrochemical charge storage device comprising an ionic transistor and an ionic capacitor,
the ionic transistor comprising:
a reservoir layer forming an ion reservoir;
a source electrode in contact with a part of the reservoir layer;
a drain electrode in contact with another part of the reservoir layer, the drain electrode and the source electrode being physically separated from each other, the source electrode and the drain electrode each being made of an electrically conductive material; and
a gate electrode of an electrically conductive material, the gate electrode being separated from the reservoir layer by an ionic conductive layer of an ionic conductive and dielectric material, the ionic conductive layer being in contact with the source electrode and with the drain electrode;
the ionic capacitor comprising two electrodes, each of the two electrodes being of an electrically conductive material, the ionic capacitor comprising an ionic conductive layer separating the two electrodes of the ionic capacitor, the ionic conductive layer of the ionic capacitor being of an ionic conductive and dielectric material;
the device further comprising a connection element configured to connect the gate electrode of the ionic transistor to a first electrode of the two electrodes of the ionic capacitor.

2. The device according to claim 1, wherein one of the source electrode and the drain electrode of the ionic transistor is connected to a second of the two electrodes of the ionic capacitor, the second electrode being distinct from the first electrode.

3. The device according to claim 1, wherein the connection element is an element configured to connect, directly or indirectly, the gate electrode of the ionic transistor to the first electrode of the ionic capacitor.

4. The device according to claim 1, wherein the connection element is one of a layer of electrically conductive material, a conductive via, a switch or a multiplexer.

5. The device according to claim 1, wherein the ion conducting layer of the ionic transistor and the ion conducting layer of the ionic capacitor are common.

6. The device according to claim 1, wherein the gate electrode of the ionic transistor and said first electrode of the ionic capacitor are common.

7. The device according to claim 2, wherein the source electrode of the ionic transistor, the drain electrode of the ionic transistor and the second electrode of the ionic capacitor are of a same electrically conductive material and have a same thickness.

8. The device according to claim 7, wherein the electrode, among the drain electrode and the source electrode, of the ionic transistor connected to the second electrode of the ionic capacitor is a connection electrode of the ionic transistor, wherein the connection electrode of the ionic transistor and the second electrode of the ionic capacitor are common.

9. The device according to claim 1, wherein the ionic transistor and the ionic capacitor are monolithically formed on a same substrate.

10. The device according to claim 9, wherein the ionic transistor and the ionic capacitor are located on a same level of the substrate.

11. The device according to claim 9, wherein the substrate comprises a recess, wherein at least a part of the ionic capacitor is housed in the recess.

12. The device according to claim 1, wherein the ionic capacitor further comprises an interlayer of an ion reservoir material, the interlayer separating the ionic conductive layer of the ionic capacitor and the electrode, among the two electrodes of the ionic capacitor, other than the first electrode.

13. A neuromorphic processing circuit of the a differential pair integrator type comprising an electrochemical charge storage device according to claim 1.

14. A method for manufacturing an electrochemical charge storage device according to claim 1, the method successively comprising:
depositing, onto a substrate, a first layer of electrically conductive material, and structuring said first layer so as to obtain a first part of first layer and a second part of first layer having no point of contact, the first part of first layer corresponding to one electrode among a source electrode and a gate electrode of the ionic transistor, the second part of first layer corresponding to the other electrode among the source electrode and the drain electrode of the ionic transistor and to an electrode of the ionic capacitor;
depositing the reservoir layer, the reservoir layer being in contact with the first part of first layer and with the second part of first layer;
depositing an ionic conductive layer of an ionic conductive and dielectric material, the ionic conductive layer at least partially covering the first part of first layer, the entire reservoir layer and at least partially the second part of first layer; and
depositing a second layer of electrically conductive material at least partially covering the ionic conductive layer, the second layer of electrically conductive material having no point of physical contact with the first layer of electrically conductive material, the second layer of electrically conductive material forming a gate electrode of the ionic transistor and another electrode of the ionic capacitor.

15. The method for manufacturing according to claim 14, wherein the deposition of at least one of the first layer of electrically conductive material, the ionic conductive layer and the second layer of electrically conductive material is a conformal deposition.
